(19) United States
(12) Patent Application Publication
(10) Pub. No.: US 2016/0041471 A1
(43) Pub. Date: Feb. 11, 2016

(54) ACIDIFIED CONDUCTIVE WATER FOR DEVELOPER RESIDUE REMOVAL

(71) Applicant: International Business Machines Corporation, Armonk, NY (US)

(72) Inventors: Guillaume D. Briend, Fishkill, NY (US); Vishal Chhabra, Fishkill, NY (US); John A. Fitzsimmons, Poughkeepsie, NY (US)

(21) Appl. No.: 14/453,882

(22) Filed: Aug. 7, 2014

(51) Int. Cl. G03F 7/40

(52) U.S. Cl. CPC G03F 7/405

(57) ABSTRACT

The present invention relates generally to semiconductor fabrication lithography and, more particularly, to a method and composition for reducing post-development defects and residues that may remain on a photoresist after development of the photoresist without causing substantial damage to the photoresist. The method may include rinsing the photoresist and the semiconductor device with ozonated acidified conductive water composed of a combination of ozone and a gaseous acid dissolved in deionized water.

### BACKGROUND

The present invention relates generally to semiconductor fabrication lithography and, more particularly, to a method and composition for reducing post-development defects and residues that may remain on a photoresist and semiconductor device after development of the photoresist.

Photoresists are commonly used in semiconductor fabrication processes where it is desired to transfer detailed patterns onto a surface. Typically, a layer of photoresist material may be deposited on the surface, followed by the selective exposure of the photoresist layer to an energy source, wherein portions of the photoresist layer are changed in character due to their exposure to the energy source. After such exposure, the photoresist layer is then developed by a wet development process employing liquid chemical solvents to selectively remove portions of the photoresist layer to provide the desired pattern. The surface may then be etched with this pattern.

### SUMMARY

According to an embodiment, a method is disclosed. The method may include: forming a mask layer on a base layer using lithographic development, the lithographic development may leave one or more post-development defects composed of basic salts; and removing the one or more post-development defects selective to the mask layer and the base layer using an ozonated acidified conductive water rinse. The ozonated acidified conductive rinse may be applied to the one or more post-development defects, the mask layer, and the base layer. The ozonated acidified conductive water rinse may leave substantially no residue.

According to another embodiment, a method is disclosed. The method may include: depositing a resist material on a base layer; removing a portion of the resist material using lithographic patterning and development to form an opening in the resist material. The lithographic patterning and development may generate post-development defects that may remain on the resist material and the base layer. The post-development defects may be composed of basic salt residues that may remain on a portion of the mask layer and a portion of the base layer. The post-development defects may be removed selective to the resist material and the base layer using an acidified conductive water rinse. The acidified conductive rinse may be applied to the post-development defects, the resist material, and the base layer. The acidified conductive water rinse may leave substantially no residue.

According to another embodiment, a rinse solution for use in removing post-development defects formed during lithographic patterning of a mask layer without substantially removing the mask layer comprising is disclosed. The rinse solution may be composed of ozonated acidified conductive water having a resistance ranging from 50,000 ohms to 500,000 ohms.

### BRIEF DESCRIPTION OF THE SEVERAL VIEWS OF THE DRAWINGS

The following detailed description, given by way of example and not intended to limit the invention solely thereto, will best be appreciated in conjunction with the accompanying drawings, in which not all structures may be shown.

FIG. 1 is a cross section view illustrating a structure including a resist layer and a base layer, according to an embodiment of the present invention.

FIG. 2 is a cross section view illustrating exposing the resist layer to a patterned energy source, according to an embodiment of the present invention.

FIG. 3 is a cross section view illustrating a development step in which a patterned portion of the resist layer is removed to form an opening, according to an embodiment of the present invention.

FIGS. 4A-4B are cross section views cross illustrating removing post-development defects using a rinse solution, according to an embodiment of the present invention.

FIG. 5 is a cross section view illustrating removing the rinse solution, according to an embodiment of the present invention.

FIG. 6 is a cross section view illustrating forming a resist layer on the base layer, according to an embodiment of the present invention.

FIG. 7 is a cross section view illustrating exposing the resist layer to the patterned energy source, according to an embodiment of the present invention.

FIG. 8 is cross section view illustrating development and removal of the resist layer, according to an embodiment of the present invention.

FIGS. 9A-9B are cross section views cross illustrating removing post-development defects using a rinse solution, according to an embodiment of the present invention.

FIG. 10 is a cross section view illustrating removing the rinse solution, according to an embodiment of the present invention.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete, and will fully convey the scope of this invention to those skilled in the art.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element such as a layer, region, or substrate is referred to as being “on”, “over”, “beneath”, “below”, or “under” another element, it may be present on or below the other element or intervening elements may also be present. In contrast, when an element is referred to as being “directly on”, “directly over”, “directly beneath”, “directly below”, or “directly contacting” another element, there may be no intervening elements present. Furthermore, the terminology used herein is for the purpose of describing particular embodiments only and is not intended to be limiting of the invention. As used herein, the singular forms “a,” “an,” and “the” are intended to include the plural forms as well, unless the context clearly indicates otherwise.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

The present invention relates generally to semiconductor fabrication lithography and, more particularly, to a method and composition for reducing post-development defects and residues that may remain on a photoresist and semiconductor device after development of the photoresist. Conventional photoresist materials may exhibit a class of post-development defects in which fragments, pieces, or particles of the original components of the photoresist material, which should have been removed, remain in and around small openings in the photoresist after the photoresist has been exposed and developed. These defects may block or partially block such openings during a subsequent etching step. The post-development defects may be basic salts that form when the developer reacts with the photoresist material. Such post-development defects may interfere with the etching of the material under the photoresist, causing micro-masking defects, or interfere with ion implantation or deposition through these openings in the photoresist.

Typically, these post-development defects may be reduced using a rinsing process or a descum process after development. Typically, the rinsing process may be conducted using a puddle rinse with deionized water (DIW), which may not effectively remove most of the post-development defects. An acidified rinse solution containing a liquid acid may be used for greater effectiveness, but may leave a residue behind. The descum process is an oxygen-based plasma process that may remove a small amount, typically a few hundred angstroms, of the photoresist along with the post-development defects. The descum process, by its nature, may cause damage to the photoresist in order to remove the post-development defects, and may negatively impact subsequent etching or ion implantation steps.

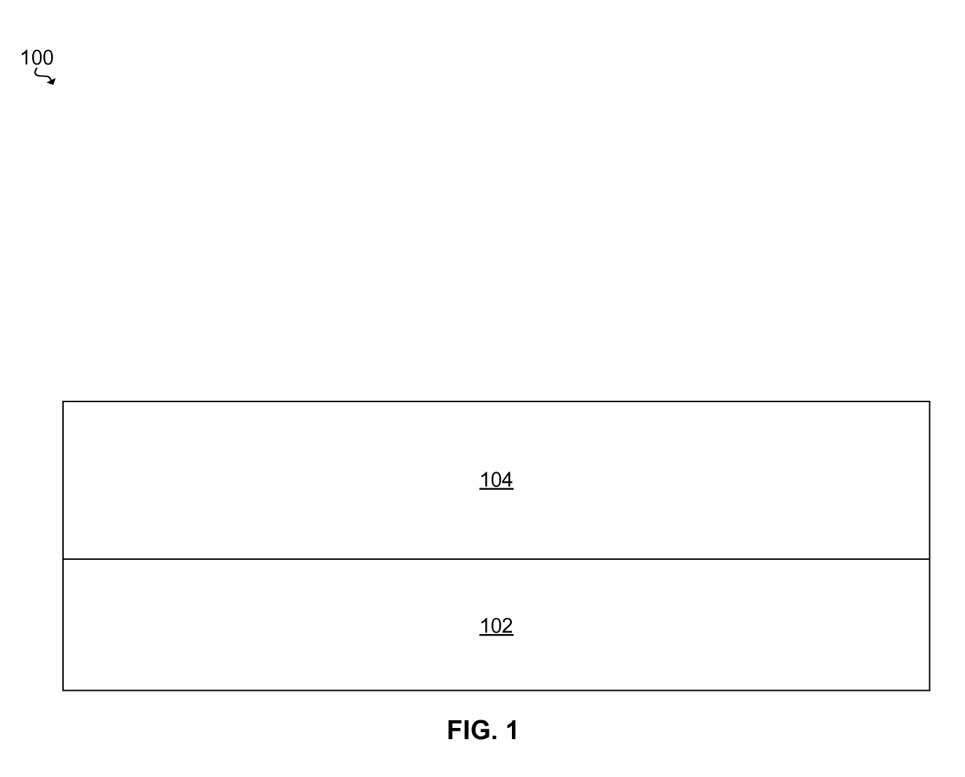

One way to remove the post-development defects in a highly controlled manner, without leaving a residue behind and without the damaging effects of the descum process, may be to use acidified conductive water that leaves no residue behind. Embodiments by which to use acidified conductive water to remove post-development defects, without damaging the photoresist, are described in detail below with reference to FIGS. 1-10.

Referring now to FIG. 1, a cross section view illustrating a structure 100 is shown. The structure may include a base layer 102 and a photoresist layer 104 (hereinafter “resist layer”). The base layer 102 may include a semiconductor substrate composed of a semiconductor material, or an insulator layer composed of a dielectric material. In an embodiment, the resist layer 104 may be composed of a conventional photoresist material based on photoacid accelerators, such as, for example, a positive tone resist. A positive tone resist is a type of photoresist in which the portion of the photoresist that is exposed to light becomes soluble to the photoresist developer. The portion of the photoresist that is unexposed remains insoluble to the photoresist developer. In another embodiment, the resist layer 104 may be composed of a conventional x-ray resist material. Although not depicted in FIG. 1, the resist layer 104 may include an anti-reflection coating (ARC) layer (not shown) first deposited on the base layer 102. The ARC layer may be composed of a conventional ARC material.

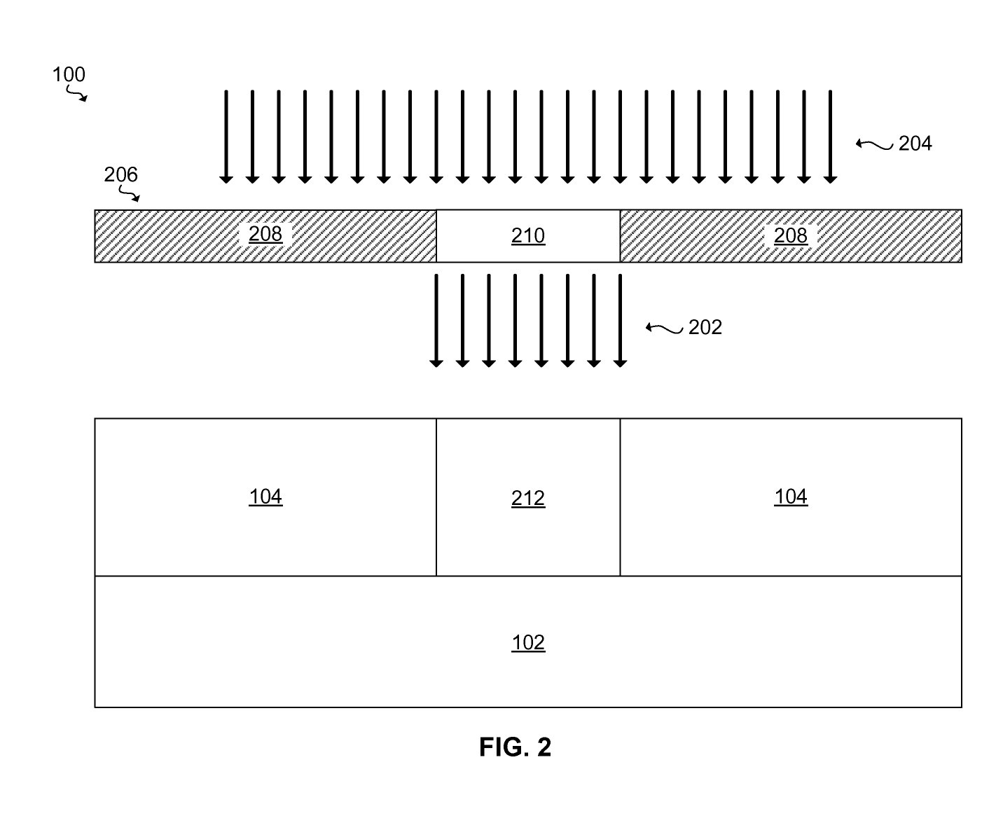

Referring now to FIG. 2, a cross section view illustrating exposing the resist layer 104 to a patterned energy source 202 is shown. A patterning mask 206 with an opaque region 208 and a transparent region 210 may be illuminated by a non-patterned energy source 204. The non-patterned energy source 204 may pass through the transparent region 210, thereby becoming a patterned energy source 202. The patterned energy source 202 may then impinge upon a patterned portion 212 of the resist layer 104. In an embodiment in which the resist layer 104 is a positive tone photoresist, the patterned portion 212 may be chemically changed or modified by the patterned energy source 202 such that it may be dissolved and removed when the resist layer 104 is exposed to a developer solution in subsequent steps. In an embodiment, the non-patterned energy source 202 may include light, such as, for example, visible light, ultra-violet light, or deep ultra-violet light. In another embodiment, the energy source may include amplified light, such as, for example a laser. In yet another embodiment, the non-patterned energy source 202 may include x-rays.

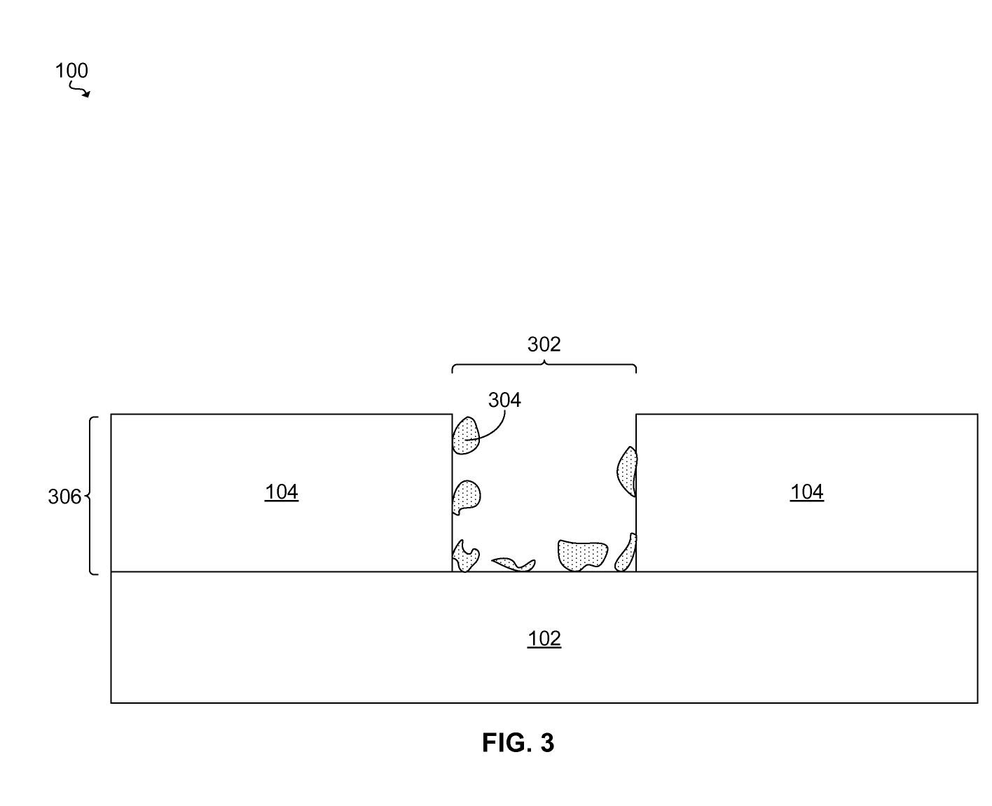

Referring now to FIG. 3, a cross section view illustrating development of the resist layer 104 is shown. FIG. 3 illustrates an embodiment in which the patterned portion 212 (FIG. 2) is removed to form an opening 302. In an embodiment in which the resist layer 104 is composed of a positive tone resist material, the development step may include exposing the photoresist layer 104 to a developer solution that may dissolve the patterned portion 212 (FIG. 2) selective to the remaining portions of the resist layer 104 and the base layer 102. The remaining portions of the resist layer 104 may be referred to as a mask layer 306. In an embodiment in which the resist layer 104 is a negative tone resist material, the development step will be of a complimentary manner, such that the unexposed area may be removed and the patterned portion 212 (FIG. 2) would remain as the mask layer 306. A conventional developer solution may be used in the development step.

Typical developer solutions may be aqueous or semi-aqueous systems having a basic pH (i.e., having a pH greater than approximately 7), often having a pH of approximately 10 or greater. These developer solutions may contain a base such as tetramethylammonium hydroxide (TMAH), ammonium silicate, or other alkaline agents. The developer solutions may also include wetting agents or surfactants to improve surface wetting and retention of the dissolved photoresist material in the developer solution.

While the development step may remove substantially all of the patterned portion 212 (FIG. 2), one or more post-development defects 304 may remain in the opening 302 and the base layer 102, among other areas. The post-development defects 304 may be basic salt by-products formed in the reaction of the developer solution with the photoresist material in the resist layer 104 and the patterned portion 212 (FIG. 2). The post-development defects 304 may manifest as, for example, solid precipitates, organic residues, particles, films, and the like.

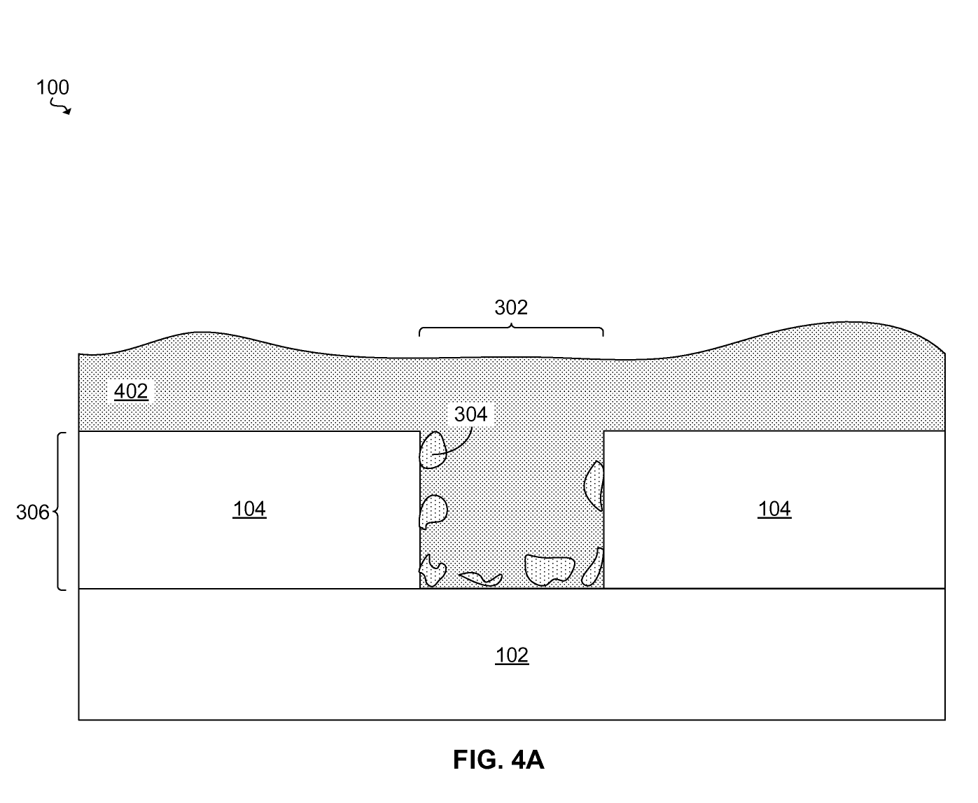

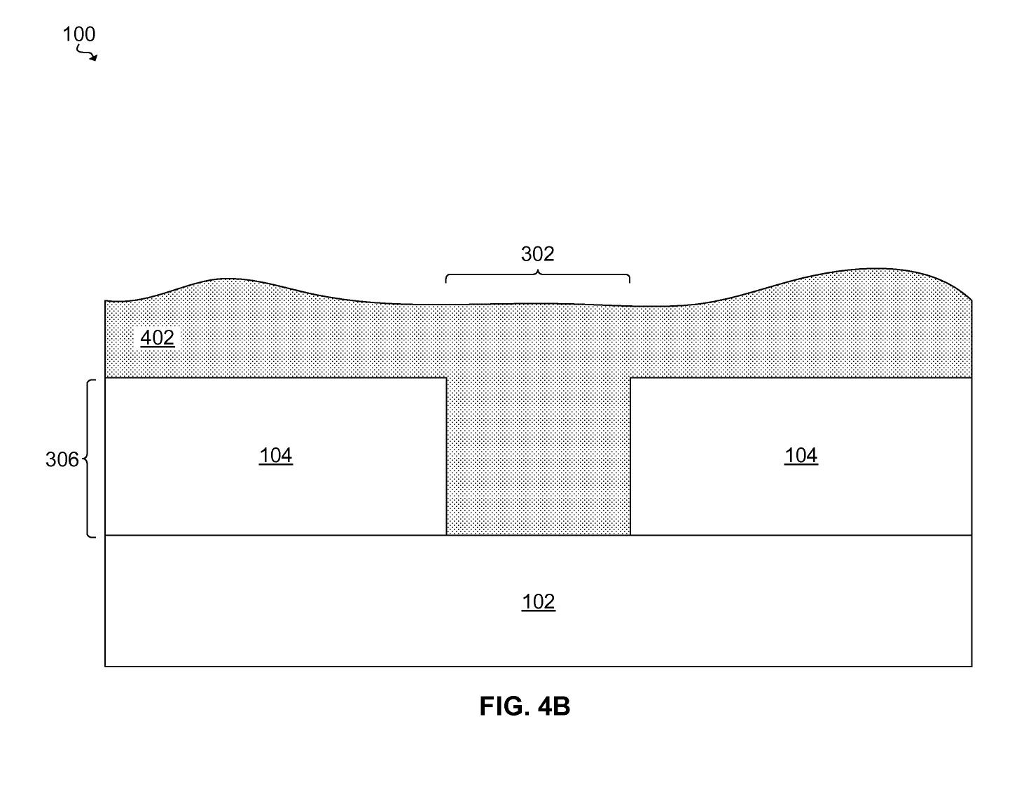

Referring now to FIGS. 4A-4B, cross section views illustrating removing the post-development defects 304 using a rinse solution 402 are shown. The rinse solution 402 may be composed of acidified conductive water that may neutralize the basic post-development defects 304 but leave no residue. In an embodiment, the acidified conductive water may be composed of a gaseous acid such as, for example, CO2, dissolved in deionized water (DIW). In another embodiment, the acidified conductive water may be composed of a mineral acid formed by dissolving a gas in aqueous solution such as hydrochloric acid (HCL). In another embodiment, the acidified conductive water may be composed of a solution of an acidic solid that thermally decomposes into a gas, such as oxalic acid, dissolved in DIW. In another embodiment, the acidified conductive water may be composed of a peroxyacid, such as, for example, peroxycarbonic acid, dissolved in DIW. In another embodiment, the acidified conductive water may be composed of a low molecular weight organic acid having a high vapor pressure that is highly soluble in water, such as, for example formic acid or acetic acid, dissolved in DIW.

In any of the above embodiments, the acid may be dissolved in the DIW such that the rinse solution 402 has a sufficient acidity to neutralize the basic post-development defects 304 without damaging the remaining portions of the resist layer 104. Therefore, the acid concentration may vary depending on the type of resist material used for the resist layer 104. The rinse solution 402 may have an acid concentration such that the electrical resistance of the rinse solution 402 may range from approximately 50,000 ohms approximately 500,000 ohms, which may be higher than the resistance of a typical rinse solution having a higher acid concentration that may damage the resist layer 104.

In another embodiment, the rinse solution 402 may be composed of the above acidified conductive water with the addition of dissolved ozone (i.e., ozonated acidified conductive water). Typically, ozone may be used in resist stripping solutions, at concentrations of approximately 15 ppm. The high concentration in the resist stripping solutions may react with the resist layer and may cause significant damage, allowing for the removal of at least a portion, and typically all, of a resist layer. In the present embodiment, the concentration of ozone in the ozonated acidified conductive water may be much lower. The concentration of ozone in the rinse solution 402 may be sufficient to neutralize the basic post-development defects 304, but not so high as to cause damage to the resist layer 104. In addition, the concentration of ozone may be sufficient to remove one or more layers of undeveloped resist material remaining in the openings. Therefore, the concentration of ozone may vary depending on the type of resist material used for the resist layer 104. In an embodiment, the concentration of ozone in the rinse solution 402 may range from approximately 0.01 ppm to approximately 8 ppm.

The rinse solution 402 may be applied to the structure using conventional rinsing techniques that incorporate rotating the structure 100 while applying the rinse solution. The rinse solution 402 may be applied at a temperature ranging from approximately 20° C. to approximately 60° C. and pressure ranging from approximately 1 atm to approximately 3 atm. In a preferred embodiment, the rinse solution 402 may be applied directly after the development step. In another embodiment, the rinse solution 402 may be applied after the development step and directly after a subsequent etching step, such as for example, reactive ion etching (RIE), used to pattern the base layer 102.

Typically, an acidified rinse may be used to reduce electrical charge in conventional resists that may be slightly basic rather than to remove defects and residues that may remain on a photoresist and semiconductor device after development of the resist as in present embodiments. In embodiments of the present invention, the rinse solution 402, whether it is acidified conductive water or ozonated acidified conductive water, may be used to neutralize and remove the post-development defects 304, which may be composed of basic salts. Because of the low concentration of ozone and the low acid concentration, the rinse solution 402 may remove the post-development defects 304 by neutralizing the basic salt residues without causing substantial damage to the remaining portions of the resist layer 104.

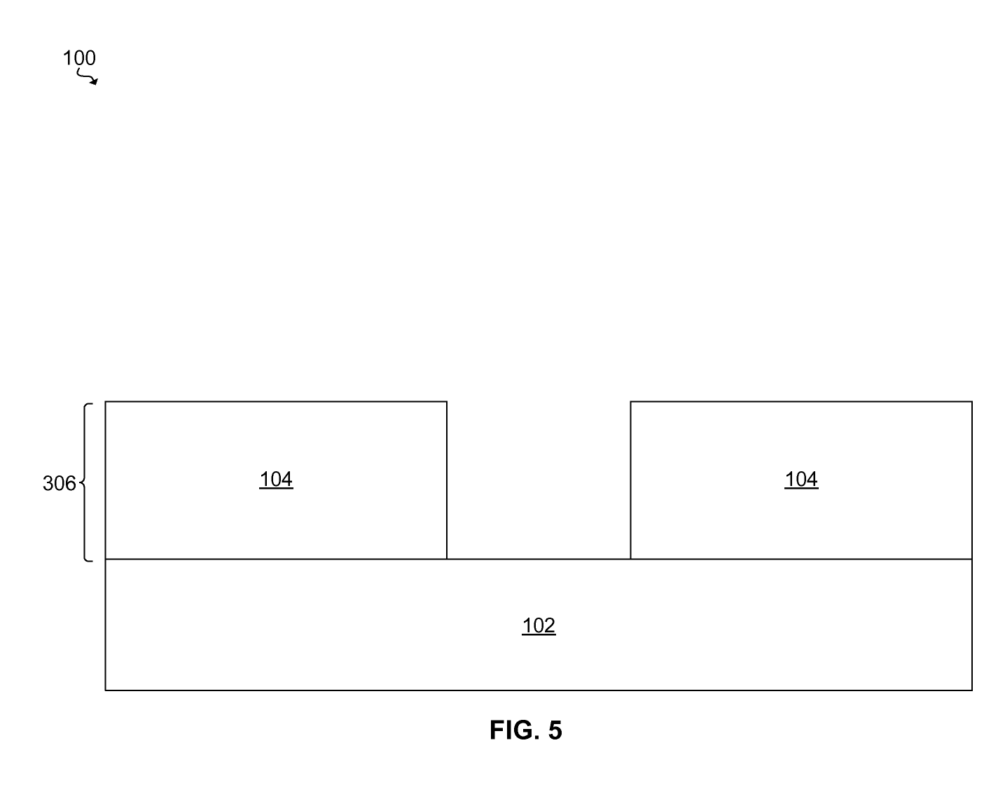

Referring now to FIG. 5, a cross section view illustrating removing the rinse solution 402 (FIGS. 4A-4B) from the structure 100. In an embodiment, the rinse solution 402 may be removed by reducing the flow of the rinse solution 402 and allowing the structure 100 to spin dry. Because the rinse solution 402 may remove the post-development defects 304 (FIG. 4A) without leaving a residue due to the dissolved acid component, the rinse solution 402 may be removed by terminating the rinsing process. In an embodiment, the structure 100 may be subjected to an elevated temperature to facilitate evaporation of the rinse solution 402. In another embodiment, an optional DIW rinse with a subsequent isopropyl alcohol (IPA) or nitrogen drying process may be performed after the rinse solution 402 is removed. After the rinse solution 402 is removed, the resist layer 104 and the base layer 102 may remain, and the post-development defects 304 may be removed.

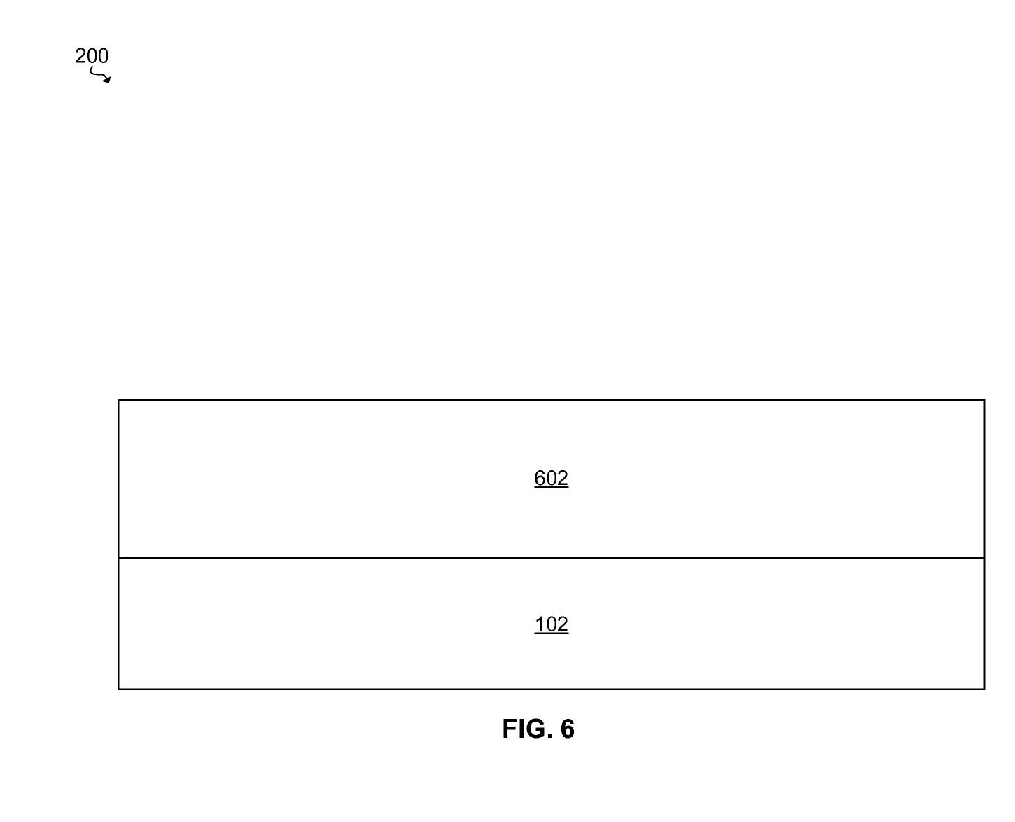

Referring now to FIG. 6, and in another embodiment, a cross section view illustrating forming a resist layer 602 on the base layer 102 to form a structure 200 is shown. The base layer 102 may be substantially similar to the base layer 102 described above with reference to FIG. 1. In an embodiment, the resist layer 602 may be composed of a conventional photoresist material based on photoacid accelerators, such as, for example, a negative tone resist. A negative tone resist is a type of photoresist in which the portion of the photoresist that is exposed to light becomes insoluble to the photoresist developer. The unexposed portion of the photoresist is dissolved by the photoresist developer. In another embodiment, the resist layer 602 may be composed of a conventional x-ray resist material. Although not depicted in FIG. 6, the resist layer 602 may include an anti-reflection coating (ARC) layer (not shown) first deposited on the base layer 102. The ARC layer may be composed of a conventional ARC material.

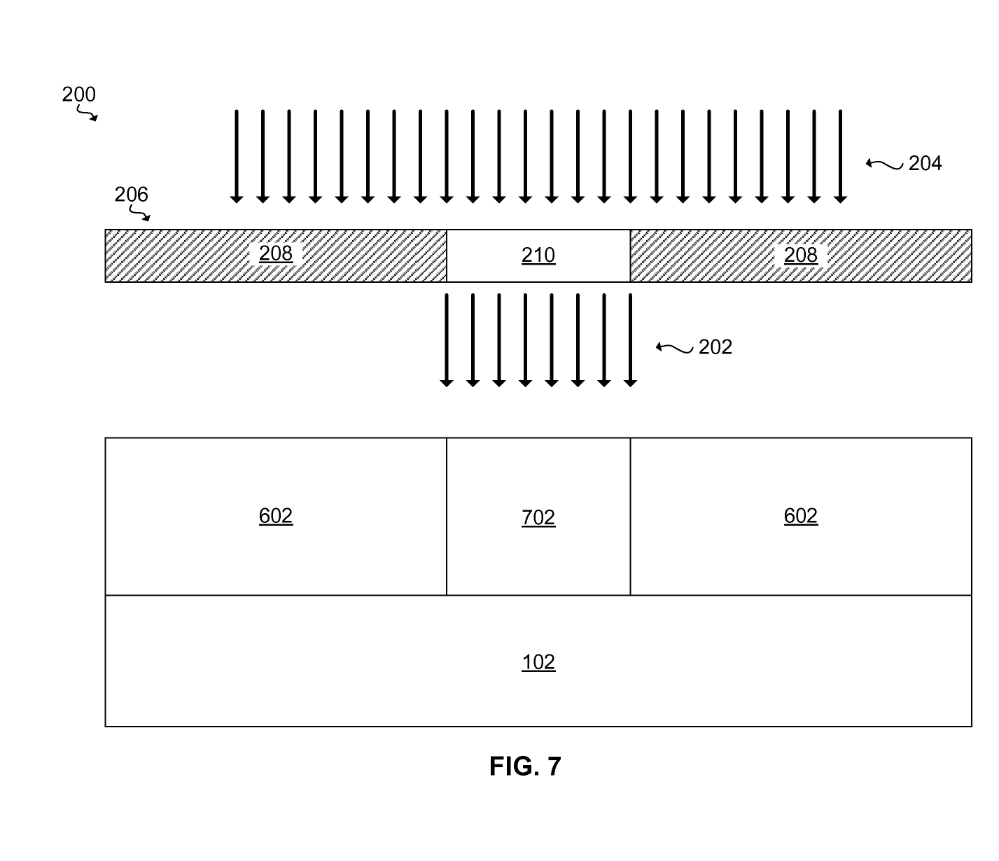

Referring now to FIG. 7, a cross section view illustrating exposing the resist layer 602 to the patterned energy source 202 is shown. The patterning mask 206 with the opaque region 208 and the transparent region 210 may be illuminated by the non-patterned energy source 204. The non-patterned energy source 204 may pass through the transparent region 210, thereby becoming a patterned energy source 202. The patterned energy source 202 may then impinge upon a patterned portion 702 of the resist layer 602. In an embodiment in which the resist layer 602 is a negative tone photoresist, the patterned portion 702 may be chemically changed or modified by the patterned energy source 202 such that it may be insoluble when the resist layer 602 is exposed to a developer solution and removed in subsequent steps. In an embodiment, the non-patterned energy source 202 may include light, such as, for example, visible light, ultra-violet light, or deep ultra-violet light. In another embodiment, the non-patterned energy source 202 may include amplified light, such as, for example a laser. In yet another embodiment, the energy source may include x-rays.

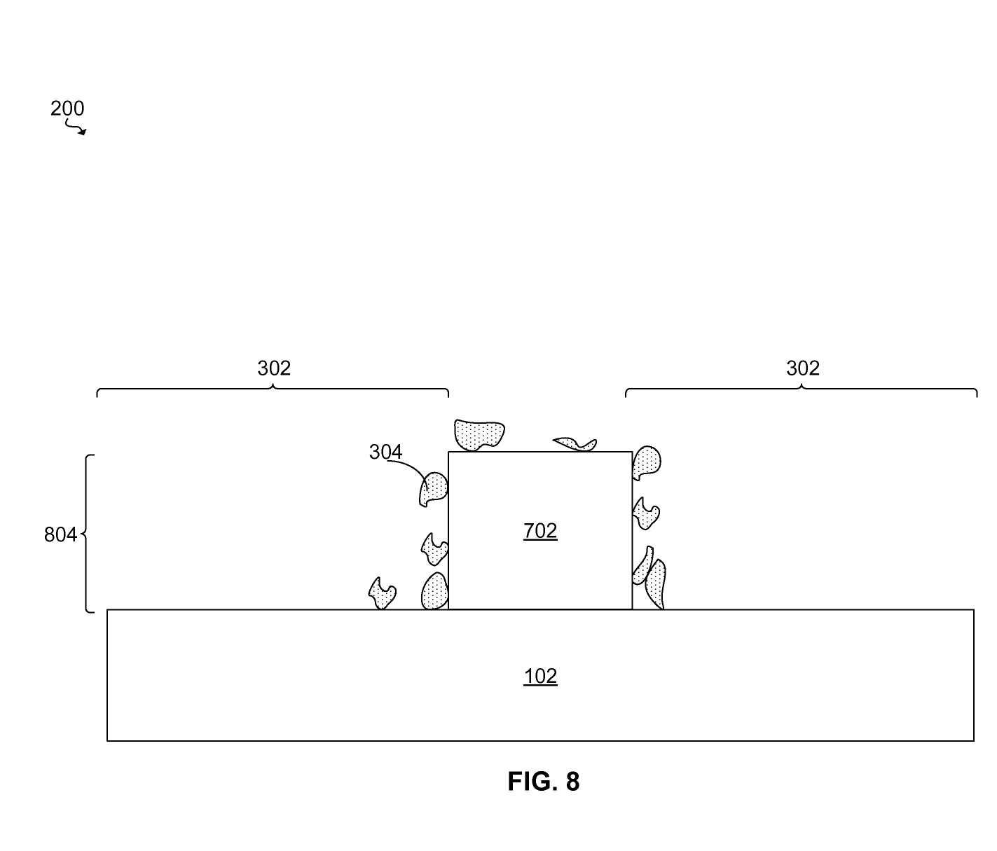

Referring now to FIG. 8, a cross section view illustrating development and removal of the resist layer 602 (FIG. 7) is shown. FIG. 8 illustrates an embodiment in which the resist layer 602 (FIG. 7) is removed to form one or more openings 302 adjacent to the patterned portion 702. In an embodiment in which the resist layer 104 is composed of a positive tone resist material, the development step may include exposing the photoresist layer 602 (FIG. 7) and the patterned portion 702 to a developer solution that may dissolve the photoresist layer 602 (FIG. 7) selective to the patterned portion 702 and the base layer 102. The remaining patterned portion 702 may be referred to as a mask layer 804. A conventional developer solution may be used in the development step.

Typical developer solutions may be aqueous or semi-aqueous systems having a basic pH (i.e., having a pH greater than approximately 7), often having a pH of approximately 10 or greater. These developer solutions may contain a base such as tetramethylammonium hydroxide (TMAH), ammonium silicate, or other alkaline agents. The developer solutions may also include wetting agents or surfactants to improve surface wetting and retention of the dissolved photoresist material in the developer solution.

Typical negative resist developer solutions may be solvent or semi-aqueous systems having a basic pH that may dissolve lower molecular weight unexposed photoresist material while leaving behind higher molecular weight exposed resist material. The negative resist developer solutions may also include wetting agents or surfactants to improve surface wetting and retention of the dissolved unexposed negative resist material.

While the development step may remove substantially all of the resist layer 602 (FIG. 7), one or more post-development defects 304 may remain on the patterned portion 702 and the base layer 102, among other areas. The post-development defects 304 may be basic salt by-products formed in the reaction of the developer solution with photoresist material in the resist layer 602 (FIG. 7) the patterned portion 702. The post-development defects 304 may manifest as, for example, solid precipitates, organic residues, particles, films, and the like.

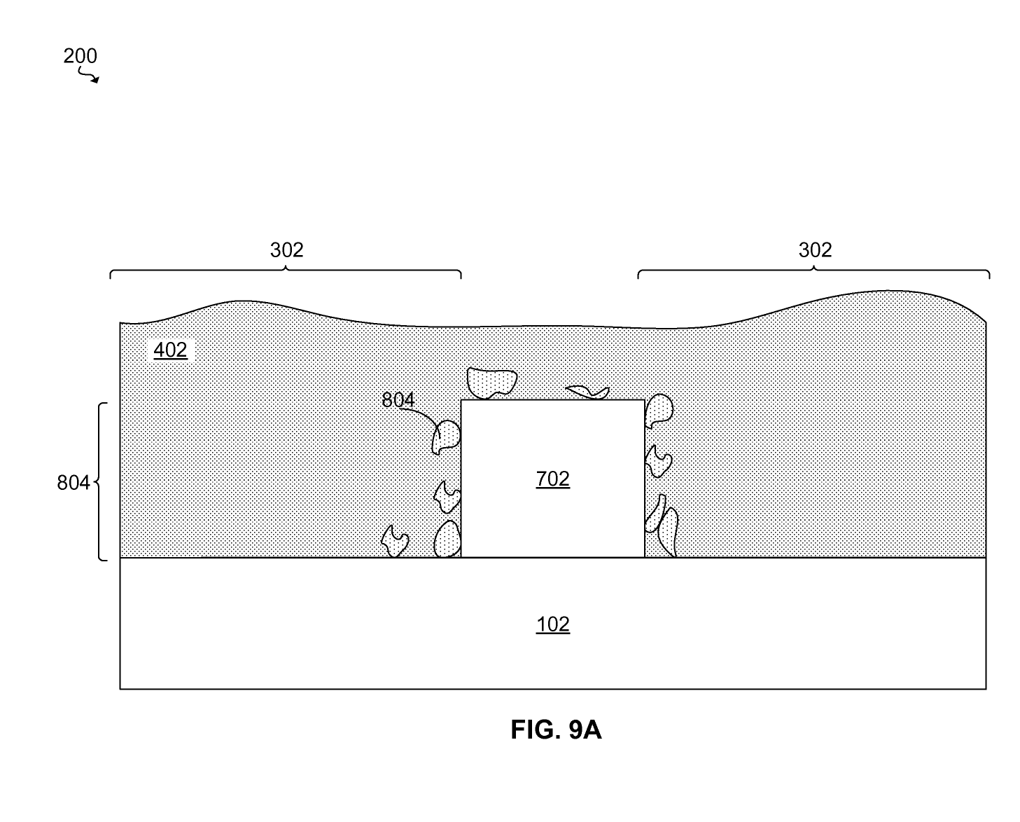

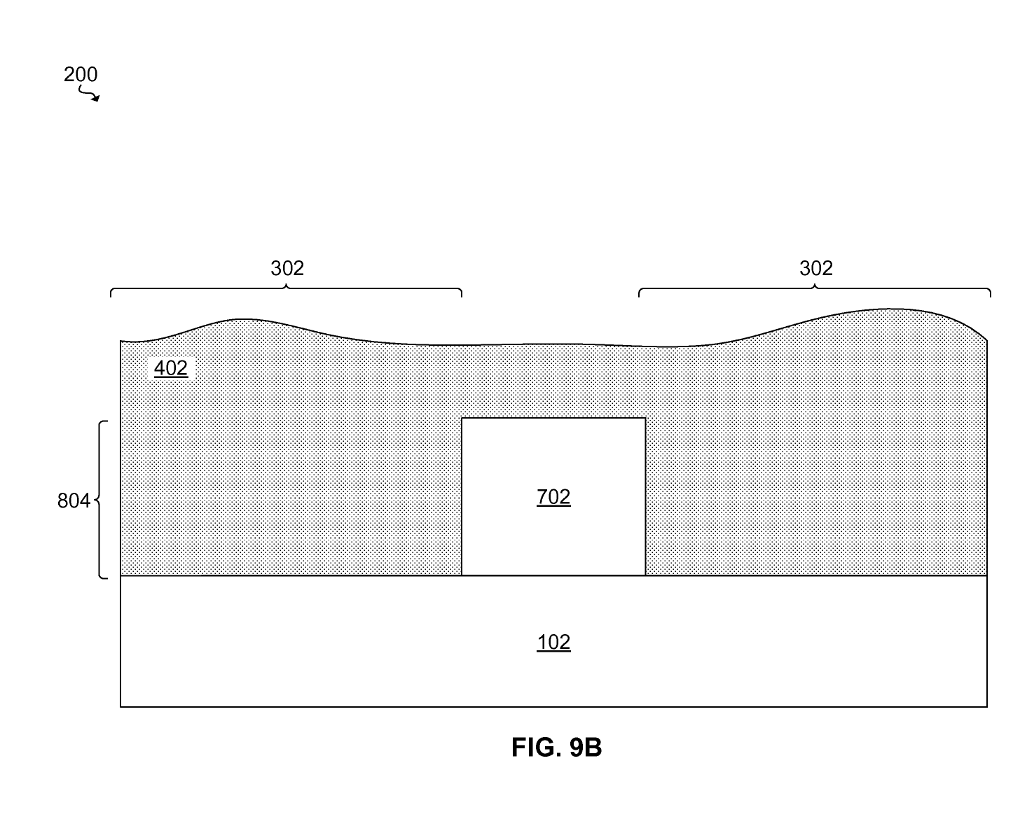

Referring now to FIGS. 9A-B, cross section views illustrating removing the post-development defects 304 using a rinse solution 402 are shown. The rinse solution 402 may be composed of acidified conductive water that may neutralize the basic post-development defects 304 but leave no residue. In an embodiment, the acidified conductive water may be composed of a gaseous acid such as, for example, CO₂, dissolved in deionized water (DIW). In another embodiment, the acidified conductive water may be composed of a mineral acid formed by dissolving a gas in aqueous solution such as hydrochloric acid (HCL). In another embodiment, the acidified conductive water may be composed of a solution of an acidic solid that thermally decomposes into a gas, such as oxalic acid, dissolved in DIW. In another embodiment, the acidified conductive water may be composed of a peroxyacid, such as, for example, peroxycarbonic acid, dissolved in DIW. In another embodiment, the acidified conductive water may be composed of a low molecular weight organic acid having a high vapor pressure that is highly soluble in water, such as, for example formic acid or acetic acid, dissolved in DIW.

In any of the above embodiments, the acid may be dissolved in the DIW such that the rinse solution 402 has a sufficient acidity to neutralize the basic post-development defects 304 without damaging the remaining portions of the patterned portion 702. Therefore, the acid concentration may vary depending on the type of resist material used for the patterned portion 702. The rinse solution 402 may have an acid concentration such that the electrical resistance of the rinse solution 402 may range from approximately 50,000 ohms approximately 500,000 ohms, which may be higher than the resistance (i.e., less conductive) of a typical rinse solution having a higher acid concentration that may damage the patterned portion 702.

In another embodiment, the rinse solution 402 may be composed of the above acidified conductive water with the addition of dissolved ozone (i.e., ozonated acidified conductive water). Typically, ozone may be used in resist stripping solutions, at concentrations of approximately 15 ppm. The high concentration in the resist stripping solutions may react with the resist layer and may cause significant damage, allowing for the removal of at least a portion, and typically all, of a resist layer. In the present embodiment, the concentration of ozone in the ozonated acidified conductive water may be much lower. The concentration of ozone in the rinse solution 402 may be sufficient to neutralize the basic post-development defects 304, but not so high as to cause damage to the patterned portion 702. In addition, the concentration of ozone may be sufficient to remove one or more layers of undeveloped resist material remaining in the openings 302. Therefore, the concentration of ozone may vary depending on the type of resist material used for the patterned portion 702. In an embodiment, the concentration of ozone in the rinse solution 402 may range from approximately 0.01 ppm to approximately 8 ppm.

The rinse solution 402 may be applied to the structure using conventional rinsing techniques that incorporate rotating the structure 100 while applying the rinse solution. The rinse solution 402 may be applied at a temperature ranging from approximately 20° C. to approximately 60° C. and pressure ranging from approximately 1 atm to approximately 3 atm. In a preferred embodiment, the rinse solution 402 may be applied directly after the development step. In another embodiment, the rinse solution 402 may be applied after the development step and directly after a subsequent etching step, such as for example, reactive ion etching (RIE), used to pattern the base layer 102.

Typically, an acidified rinse may be used to reduce electrical charge in conventional resists that may be slightly basic rather than to remove defects and residues that may remain on a photoresist and semiconductor device after development of the resist as in present embodiments. In embodiments of the present invention, the rinse solution 402, whether it is acidified conductive water or ozonated acidified conductive water, may be used to neutralize and remove the post-development defects 304, which may be composed of basic salts. Because of the low concentration of ozone and the low acid concentration, the rinse solution 402 may remove the post-development defects 304 by neutralizing the basic salt residues without causing substantial damage to the remaining portions of the patterned portion 702.

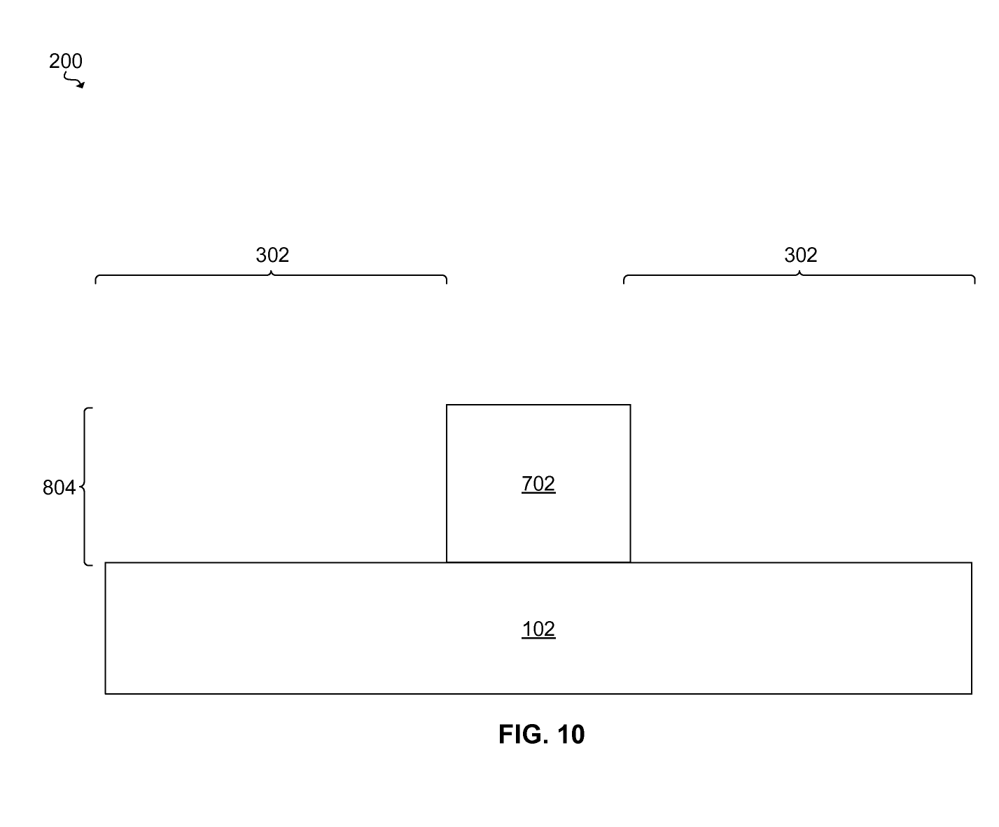

Referring now to FIG. 10, a cross section view illustrating removing the rinse solution 402 (FIGS. 4A-4B) from the structure 200. In an embodiment, the rinse solution 402 may be removed by reducing the flow of the rinse solution 402 and allowing the structure 200 to spin dry. Because the rinse solution 402 may remove the post-development defects 304 (FIG. 9A) without leaving a residue due to the dissolved acid component, the rinse solution 402 may be removed by terminating the rinsing process. In an embodiment, the structure 200 may be subjected to an elevated temperature to facilitate evaporation of the rinse solution 402. In another embodiment, an optional DIW rinse with a subsequent isopropyl alcohol (IPA) or nitrogen drying process may be performed after the rinse solution 402 is removed. After the rinse solution 402 is removed, the patterned portion 702 and the base layer 102 may remain substantially undamaged, and the post-development defects 304 may be removed.

Embodiments of the present invention may improve the fidelity of a photoresist image transfer process by removing post-development defects from a resist layer and a base layer using acidified conductive water that may leave no residue and may maintain the structure of the patterned resist layer. The post-development defects may be basic salt artifacts that remain on the resist layer and the base layer that form as a result of the developer reacting with light-exposed portions of the resist layer. The post-development defects may block the patterned openings in the resist layer, and may cause defects in subsequent etching steps of the base layer. Embodiments in which the rinse solution is composed of an acidified conductive water or an ozonated acidified conductive water may neutralize and remove the post-development defects without leaving a residue, unlike conventional rinsing techniques, and without damaging the resist layer, unlike conventional descumming techniques. Because the rinse solution may leave no reside, it may then easily be removed.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A method comprising:
forming a mask layer on a base layer using lithographic development, wherein the lithographic development leaves one or more post-development defects comprises basic salts;
removing the one or more post-development defects selective to the mask layer and the base layer using an ozonated acidified conductive water rinse, wherein the ozonated acidified conductive rinse is applied to the one or more post-development defects, the mask layer, and the base layer, and wherein the ozonated acidified conductive water rinse leaves substantially no residue.

2. The method of claim 1, wherein the one or more post-development defects are present on a portion of the mask layer and a portion of the base layer.

3. The method of claim 1, wherein the forming the mask layer on the base layer using lithographic development comprises:
depositing a positive tone resist material on the base layer;
exposing the positive tone resist material to a patterning source to form a patterned portion and the mask layer, the mask layer comprising a non-patterned portion of the positive tone resist material;
removing only the patterned portion using a developer solution.

4. The method of claim 1, wherein the forming the mask layer on the base layer using lithographic development comprises:
depositing a negative tone resist material on the base layer;
exposing the negative tone resist material to a patterning source to form the mask layer and a non-patterned portion, the mask layer comprising a patterned portion of the negative tone resist material;
removing only the non-patterned portion using a developer solution.

5. The method of claim 1, wherein the removing the one or more post-development defects selective to the mask layer and the base layer using the ozonated acidified conductive water rinse comprises:
neutralizing the one or more post-development defects with a rinse solution comprising ozone dissolved in deionized water, the ozone having a concentration ranging from 0.01 ppm to 8.0 ppm.

6. The method of claim 1, wherein the removing the one or more post-development defects selective to the mask layer and the base layer using the ozonated acidified conductive water rinse comprises:
neutralizing the one or more post-development defects with a rinse solution comprising a gaseous acid dissolved in deionized water.

7. The method of claim 1, wherein the removing the one or more post-development defects selective to the mask layer and the base layer using the ozonated acidified conductive water rinse comprises:
neutralizing the one or more post-development defects with a rinse solution comprising a mineral acid formed by dissolving a gas in aqueous acid solution.

8. The method of claim 1, wherein the removing the one or more post-development defects selective to the mask layer and the base layer using the ozonated acidified conductive water rinse comprises:
neutralizing the one or more post-development defects with a rinse solution comprising an acidic solid that thermally decomposes into a gas dissolved in deionized water.

9. The method of claim 1, wherein the removing the one or more post-development defects selective to the mask layer and the base layer using the ozonated acidified conductive water rinse comprises:
neutralizing the one or more post-development defects with a rinse solution comprising a peroxyacid dissolved in deionized water.

10. The method of claim 1, wherein the removing the one or more post-development defects selective to the mask layer and the base layer using the ozonated acidified conductive water rinse comprises:
neutralizing the one or more post-development defects with a rinse solution comprising a low molecular weight organic acid having a high vapor pressure that is highly soluble in water dissolved in deionized water.

11. A method comprising:
depositing a resist material on a base layer;
removing a portion of the resist material using lithographic patterning and development to form an opening in the resist material, said lithographic patterning and development generating post-development defects that remain on the resist material and the base layer, the post-development defects comprising basic salt residues that remain on a portion of the mask layer and a portion of the base layer; and
removing the post-development defects selective to the resist material and the base layer using an acidified conductive water rinse, wherein the acidified conductive rinse is applied to the post-development defects, the resist material, and the base layer, and wherein the acidified conductive water rinse leaves substantially no residue.

12. The method of claim 10, wherein the removing the post-development defects selective to the resist material and the base layer using the acidified conductive water rinse comprises:
neutralizing the post-development defects with a rinse solution comprising a gaseous acid dissolved in deionized water.

13. The method of claim 10, wherein the removing the post-development defects selective to the resist material and the base layer using the acidified conductive water rinse comprises:
neutralizing the post-development defects with a rinse solution comprising ozone dissolved in deionized water, the ozone having a concentration ranging from 0.01 ppm to 8.0 ppm.

14. A rinse solution for use in removing post-development defects formed during lithographic patterning of a mask layer without substantially removing the mask layer comprising:
ozonated acidified conductive water comprising ozone dissolved in deionized water, wherein the concentration of ozone ranges from 0.01 ppm to 8.0 ppm.

15. The rinse solution of claim 14, wherein the ozonated acidified conductive water has a resistance ranging from 50,000 ohms to 500,000 ohms.

16. The rinse solution of claim 14, wherein the ozonated acidified conductive water comprises:
a gaseous acid dissolved in deionized water.

17. The rinse solution of claim 14, wherein the ozonated acidified conductive water comprises:
a mineral acid formed by dissolving a gas in aqueous acid solution.

18. The rinse solution of claim 14, wherein the ozonated acidified conductive water comprises:
an acidic solid that thermally decomposes into a gas dissolved in deionized water.

19. The rinse solution of claim 14, wherein the ozonated acidified conductive water comprises:
a peroxyacid dissolved in deionized water.

20. The rinse solution of claim 14, wherein the ozonated acidified conductive water comprises:
a low molecular weight organic acid having a high vapor pressure that is highly soluble in water dissolved in deionized water.
